(19) United States
(12) Patent Application Publication
(10) Pub. No.: US 2007/0290379 A1
(43) Pub. Date: Dec. 20, 2007

(54) Hydrophobic compositions for electronic applications

(76) Inventors: Thomas E. Dueber, Wilmington, DE (US); John D. Summers, Chapel Hill, NC (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/453,388

(22) Filed: Jun. 15, 2006

(51) Int. Cl. H01L 23/29

(52) U.S. Cl. 257/792

(57) ABSTRACT

Disclosed area compositions comprising: a polyimide resin with a water absorption of 2% or less and, optionally, one or more of an electrically insulated filler, a defoamer and a colorant and one or more organic solvents. The compositions are useful as encapsulants and have a consolidation temperature of 190° C. or less.

### FIELD OF THE INVENTION

This invention relates to compositions, and the use of such compositions for protective coatings. The compositions are used to protect electronic device structures, particularly embedded fired-on-foil ceramic capacitors, from exposure to printed wiring board processing chemicals and for environmental protection.

### TECHNICAL BACKGROUND OF THE INVENTION

Electronic circuits require passive electronic components such as resistors, capacitors, and inductors. A recent trend is for passive electronic components to be embedded or integrated into the organic printed circuit board (PCB). The practice of embedding capacitors in printed circuit boards allows for reduced circuit size and improved circuit performance. Embedded capacitors, however, must meet high reliability requirements along with other requirements, such as high yield and performance. Meeting reliability requirements involves passing accelerated life tests. One such accelerated life test is exposure of the circuit containing the embedded capacitor to 1000 hours at 85% relative humidity, 85° C. under 5 volts bias. Any significant degradation of the insulation resistance would constitute failure.

High capacitance ceramic capacitors embedded in printed circuit boards are particularly useful for decoupling applications. High capacitance ceramic capacitors may be formed by “fired-on-foil” technology. Fired-on-foil capacitors may be formed from thick-film processes as disclosed in U.S. Pat. No. 6,317,023B1 to Felten or thin-film processes as disclosed in U.S. Patent Application 20050011857 A1 to Borland et al.

Thick-film fired-on-foil ceramic capacitors are formed by depositing a thick-film capacitor dielectric material layer onto a metallic foil substrate, followed by depositing a top copper electrode material over the thick-film capacitor dielectric layer and a subsequent firing under copper thick-film firing conditions, such as 900-950° C. for a peak period of 10 minutes in a nitrogen atmosphere.

The capacitor dielectric material should have a high dielectric constant (K) after firing to allow for manufacture of small high capacitance capacitors suitable for decoupling. A high K thick-film capacitor dielectric is formed by mixing a high dielectric constant powder (the “functional phase”) with a glass powder and dispersing the mixture into a thick-film screen-printing vehicle.

During firing of the thick-film dielectric material, the glass component of the dielectric material softens and flows before the peak firing temperature is reached, coalesces, encapsulates the functional phase, and finally forms a monolithic ceramic/copper electrode film.

The foil containing the fired-on-foil capacitors is then laminated to a prepreg dielectric layer, capacitor component face down to form an inner layer and the metallic foil may be etched to form the foil electrodes of the capacitor and any associated circuitry. The inner layer containing the fired-on-foil capacitors may now be incorporated into a multilayer printed wiring board by conventional printing wiring board methods.

The fired ceramic capacitor layer may contain some porosity and, if subjected to bending forces due to poor handling, may sustain some microcracks. Such porosity and microcracks may allow moisture to penetrate the ceramic structure and when exposed to bias and temperature in accelerated life tests may result in low insulation resistance and failure.

In the printed circuit board manufacturing process, the foil containing the fired-on-foil capacitors may also be exposed to caustic stripping photoresist chemicals and a brown or black oxide treatment. This treatment is often used to improve the adhesion of copper foil to prepreg. It consists of multiple exposures of the copper foil to caustic and acid solutions at elevated temperatures. These chemicals may attack and partially dissolve the capacitor dielectric glass and dopants. Such damage often results in ionic surface deposits on the dielectric that results in low insulation resistance when the capacitor is exposed to humidity. Such degradation also compromises the accelerated life test of the capacitor.

It is also important that, once embedded, the encapsulated capacitor maintain its integrity during downstream processing steps such as the thermal excursions associated with solder reflow cycles or overmold baking cycles. Delaminations and/or cracks occurring at any of the various interfaces of the construction or within the layers themselves could undermine the integrity of the embedded capacitor by providing an avenue for moisture penetration into the assembly.

An approach to rectify these issues is needed. Various approaches to improve embedded passives have been tried. An example of an encapsulant composition used to reinforce embedded resistors may be found in U.S. Pat. No. 6,860,000 to Felten. A further example of an encapsulant composition to protect embedded resistors is found in (EL0538 US NA, Ser. No. 10/754,348).

### SUMMARY OF THE INVENTION

Compositions are disclosed comprising: a polyimide with water absorption of 2% or less; optionally one or more of an electrically insulated filler, a defoamer and a colorant and one or more organic solvents. The compositions have a consolidation temperature of 190° C. or less. Optionally, a hindered hydrophobic epoxy may be added to the composition.

A fired-on-foil ceramic capacitor, coated with an encapsulant of the disclosed composition and embedded in a printed wiring board or integrated circuit (IC) package structure, is also disclosed wherein said encapsulant provides protection to the capacitor from moisture and printed wiring board chemicals prior to and after embedding into the printed wiring board and said embedded capacitor structure possesses enhanced ability to pass 1000 hours of accelerated life testing conducted at 85° C., 85% relative humidity under 5 volts of DC bias. The embedded capacitor structure also possesses the ability to remain intact during thermal excursions, such as solder reflow cycles typically associated with the circuit board production process.

Compositions are also disclosed comprising: a polyimide with water absorption of 2% or less; optionally one or more electrically insulated fillers, defoamers and colorants and an organic solvent. The compositions have a consolidation temperature of 190° C. or less.

The invention is also directed to a method of encapsulating a fired-on-foil ceramic capacitor comprising: a polyimide with a water absorption of 2% or less, optionally one or more of an inorganic electrically insulating filler, a defoamer and a colorant, and one or more of an organic solvent to provide an uncured composition; applying the uncured composition to coat a fired-on-foil ceramic capacitor; and heating the applied composition at a temperature of equal to or less than 190° C.

The compositions containing the organic materials can be applied as an encapsulant to any other electronic component or mixed with inorganic electrically insulating fillers, defoamers, and colorants, and applied as an encapsulant to any electronic component.

According to common practice, the various features of the drawings are not necessarily drawn to scale. Dimensions of various features may be expanded or reduced to more clearly illustrate the embodiments of the invention.

### BRIEF DESCRIPTION OF THE DRAWINGS

FIG. 1A shows electrical materials screen printed on an alumina substrate to form a pattern.

FIG. 1B shows a protrusion that allows connections at a later stage.

FIG. 1C shows dielectric material screen printed onto electrode 130 to form a first dielectric layer. After the first dielectric layer is dried, a second dielectric layer is applied.

FIG. 1D shows a plan view of the dielectric pattern.

FIG. 1E shows copper paste printed over a second layer.

FIG. 1F shows the pattern used in screen printing an encapsulant pattern through a mesh screen over the capacitor electrode and dielectric.

FIG. 1G shows a side view of the final stack after the screen printing of the encapsulant layer.

FIGS. 2A-2G show a fired on foil capacitor made using the processes described in Example 12.

### DETAILED DESCRIPTION OF THE INVENTION

Compositions are disclosed comprising a polyimide with water absorption of 2% or less, an organic solvent, and optionally one or more of an inorganic electrically insulating filler, a defoamer and a colorant dye. The amount of water absorption is determined by ASTM D-570, which is a method known to those skilled in the art. Optionally, a hindered hydrophobic epoxy may be added to the composition.

A fired-on-foil ceramic capacitor coated with an encapsulant and embedded in a printed wiring board is also disclosed. The application and processing of the encapsulant is designed to be compatible with printed wiring board and IC package processes and provides protection to the fired-on-foil capacitor from moisture and printed wiring board fabrication chemicals prior to and after embedding into the structure. Application of said encapsulant to the fired-on-foil ceramic capacitor allows the capacitor embedded inside the printed wiring board to possess enhanced ability to survive 1000 hours of accelerated life testing conducted at 85° C., 85% relative humidity under 5 volts of DC bias.

Applicants determined that the most stable polymer matrix is achieved with the use of polyimides that also have low moisture absorption of 2% or less, preferably 1.5% or less and more preferably 1% or less. Polymers used in the compositions with water absorption of 1% or less tend to provide consolidated materials with preferred protection characteristics.

Generally, the polyimide component of the present invention can be represented by the general formula,

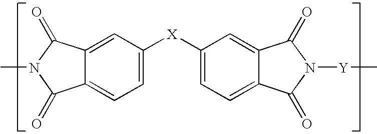

where X can be equal to C(CF₃)₂, SO₂, O, Chemical bond, C(CF₃)phenyl, C(CF₃)CF₂CF₃, C(CF₂CF₃)phenyl (and combinations thereof); and where Y is derived from a diamine component comprising from 0 to 30 mole percent of a phenolic-containing diamine selected from the group consisting of 2,2′-bis(3-amino4-hydroxyphenyl)hexafluoropropane (6F-AP), 3,3′-dihydroxy-4,4′-diaminobiphenyl (HAB), 2,4-diaminophenol, 2,3-diaminophenol, 3,3′-diamino4,4′-dihydroxybiphenyl, and 2,2′-bis(3-amino4-hydroxyphenyl)hexafluoropropane.

Diamines useful in comprising the remaining portion of the diamine component (i.e., that portion comprising from about 70 to 100 mole percent of the total diamine component) can be 3,4′-diaminodiphenyl ether (3,4′-ODA), 4,4′-diamino-2,2′-bis(trifluoromethyl)biphenyl (TFMB), 3,3′,5,5′-tetramethylbenzidine, 2,3,5,6-tetramethyl-1,4-phenylenediamine, 3,3′-diaminodiphenyl sulfone, 3,3′dimethylbenzidine, 3,3′-bis(trifluoromethyl)benzidine, 2,2′-bis-(p-aminophenyl)hexafluoropropane, bis(trifluoromethoxyl)benzidine (TFMOB), 2,2′-bis(pentafluoroethoxy)benzidine (TFEOB), 2,2′-trifluoromethyl4,4′-oxydianiline (OBABTF), 2-phenyl-2-trifluoromethyl-bis(p-aminophenyl)methane, 2-phenyl-2-trifluoromethyl-bis(m-aminophenyl)methane, 2,2′-bis(2-heptafluoroisopropoxy-tetrafluoroethoxy)benzidine (DFPOB), 2,2-bis(m-aminophenyl)hexafluoropropane (6-FmDA), 2,2-bis(3-amino4-methylphenyl)hexafluoropropane, 3,6-bis(trifluoromethyl)-1,4-diaminobenzene (2TFMPDA), 1-(3,5-diaminophenyl)-2,2-bis(trifluoromethyl)-3,3,4,4,5,5,5-heptafluoropentane, 3,5-diaminobenzotrifluoride (3,5-DABTF), 3,5-diamino-5-(pentafluoroethyl)benzene, 3,5-diamino-5-(heptafluoropropyl)benzene, 2,2′-dimethylbenzidine (DMBZ), 2,2′,6,6′-tetramethylbenzidine (TMBZ), 3,6-diamino-9,9-bis(trifluoromethyl)xanthene (6FCDAM), 3,6-diamino-9-trifluoromethyl-9-phenylxanthene (3FCDAM), 3,6-diamino-9,9-diphenyl xanthene. These diamines can be used alone or in combination with one another.

The present inventors found that if more than about 30 mole percent of the diamine component is a phenolic containing diamine, the polyimide may be susceptible to unwanted water absorption. The diamine component of the present invention can typically comprise from about 0 to about 30 mole percent of a phenolic-containing diamine to be effective.

The polyimides of the invention are prepared by reacting a suitable dianhydride (or mixture of suitable dianhydrides, or the corresponding diacid-diester, diacid halide ester, or tetracarboxylic acid thereof) with one or more selected diamines. The mole ratio of dianhydride component to diamine component is preferably from between 0.9 to 1.1. Preferably, a slight molar excess of dianhydrides or diamines can be used at mole ratio of about 1.01 to 1.02. End capping agents, such as phthalic anhydride, can be added to control chain length of the polyimide.

Some dianhydrides found to be useful in the practice of the present invention, i.e., to prepare the polyimide component, can be 3,3′,4,4′-diphenylsulfone tetracarboxylic dianhydride (DSDA), 2,2-bis(3,4-dicarboxyphenyl)1,1,1,3,3,3-hexafluoropropane dianhydride (6-FDA), 1-phenyl-1,1-bis(3,4-dicarboxyphenyl)-2,2,2-trifluoroethane dianhydride, 1,1,1,3,3, 4,4,4-octylfluoro-2,2-bis(3,4-dicarboxyphenyl)butane dianhydride, 1-phenyl-2,2,3,3,3-pentafluoro-1,1-bis(3,4-dicarboxylphenyl)propane dianhydride, 4,4′-oxydiphthalic anhydride (ODPA), 2,2′-bis(3,4-dicarboxyphenyl)propane dianhydride, 2,2′-bis(3,4-dicarboxyphenyl)-2-phenylethane dianhydride, 2,3,6,7-tetracarboxy-9-trifluoromethyl-9-phenylxanthene dianhydride (3FCDA), 2,3,6,7-tetracarboxy-9,9-bis(trifluoromethyl)xanthene dianhydride (6FCDA), 2,3,6,7-tetracarboxy-9-methyl-9-trifluoromethylxanthene dianhydride (MTXDA), 2,3,6,7-tetracarboxy-9-phenyl-9-methylxanthene dianhydride (MPXDA), 2,3,6,7-tetracarboxy-9,9-dimethylxanthene dianhydride (NMXDA) and combinations thereof. These dianhydrides can be used alone or in combination with one another.

The compositions include an organic solvent. The choice of solvent or mixtures of solvents will depend in-part on the resins used in the composition. Any chosen solvent or solvent mixtures must dissolve the resins and not be susceptible to separation when exposed to cold temperatures, for example. An exemplary list of solvents is selected from the group consisting of terpineol, ether alcohols, cyclic alcohols, ether acetates, ethers, acetates, cyclic lactones, and aromatic esters. Solvents known to be useful in accordance with the practice of the present invention include organic liquids having both (i.) a Hanson polar solubility parameter between and including any two of the following numbers 2.1, 2.2, 2.3, 2.4, 2.5, 2.6, 2.7, 2.8, 2.9 and 3.0, and (ii) a normal boiling point ranging from between and including any two of the following numbers 200, 210, 220, 230,240, 250 and 260° C. In one embodiment of the present invention, a useful solvent is selected from one or more dibasic acid ester solvents including, but not limited to, DuPont DBE® solvents including dimethyl succinate, dimethyl glutarate and dimethyl adipate. Other useful solvents include propyleneglycol diacetate (PGDA), Dowanol® PPh, butyl carbitol acetate, carbitol acetate and mixtures of these. Co-solvents may be added provided that the composition is still soluble, performance in screen-printing is not adversely affected, and lifetime storage is not adversely affected.

Another advantage to using the solvents disclosed in the present invention is that in certain embodiments, very little, if any, precipitation of the polyimide is observed when handling a paste composition. Also, the use of a polyamic acid solution may be avoided. Instead of using a polyamic acid, which can be thermally imidized to the polyimide later during processing, an already formed polyimide is used. This allows for lower curing temperatures to be used, temperatures not necessary to convert, to near completion, a polyamic acid to a polyimide. In short, the resulting solutions can be directly incorporated into a liquid or paste composition for coating and screen-printing applications without having to cure the polyimide.

Most encapsulant compositions are applied to a substrate or component by screen printing a formulated composition, although stencil printing, dispensing, doctor blading into photoimaged or otherwise preformed patterns, or other techniques are possible.

Thick-film encapsulant pastes must be formulated to have appropriate characteristics so that they can be printed readily. Thick-film encapsulant compositions, therefore, include an organic solvent suitable for screen printing and optionally defoaming agents, colorants and finely divided inorganic fillers as well as the resins. The defoamers help to remove entrapped air bubbles after the encapsulant is printed. Applicants determined that silicone containing organic defoamers are particularly suited for defoaming after printing. The finely divided inorganic fillers impart some measure of thixotropy to the paste, thereby improving the screen printing rheology. Applicants determined that fumed silica is particularly suited for this purpose. Colorants may also be added to improve automated registration capability. Such colorants may be organic dye compositions, for example. The composition may also comprise a photopolymer for photodefining the encapsulant for use with very fine features. The organic solvent should provide appropriate wettability of the solids and the substrate, have sufficiently high boiling point to provide long screen life and a good drying rate. The organic solvent along with the polymer also serves to disperse the finely divided insoluble inorganic fillers with an adequate degree of stability.

Because screen-printing is often the method of choice for PTF resistors, a paste in accordance with the present invention must generally remain stable for reasonably long exposures to ambient moisture (i.e., while the paste resides on the screen). If the polyimide/epoxy solution is not stable to moisture absorption, the polyimide component can precipitate (which is undesirable), making the paste unusable and thereby requiring considerable effort to remove the residual “damaged paste” from the screen. Additionally, excessive water uptake can also cause the paste's viscosity to drift, thus altering the printed resistor thickness and ultimately the cured resistance.

Polyimides are generally insoluble. The few polyimides that are soluble are only soluble in select polar organic solvents. But, many polar organic solvents are hydroscopic and absorb water from the ambient environment. Often, the relative humidity of an atmosphere is sufficiently high enough that water absorption into the composition is significant. The water in the composition and in the polyimide solutions can cause the polyimide to precipitate, which essentially renders the composition unusable for most purposes. The composition must be discarded, and the screen may be damaged in attempts to remove intractable paste plugging the holes in the screen.

The polyimides of the present invention can be made by thermal and chemical imidization using a different solvent as otherwise described herein. The polyimide component can be removed from the solvent by precipitation in a non-solvent such as methanol, then re-dissolved in a solvent disclosed earlier herein. Using a thermal method, the dianhydride can be added to a solution of the diamine in any of the following polar solvents, m-cresol, 2-pyrrolidone, N-methylpyrrolidone (NMP), N-ethylpyrrolidone, N-vinylpyrrolidone), N,N′-dimethyl-N,N′-propylene urea (DMPU), cyclohexylpyrrolidone (CHP), N,N-dimethylacetamide (DMAc), N,N-dimethylformamide (DMF) and γ-butyrolactone (BLO). The reaction temperature for preparation of the polyamic acid or polyamic acid ester is typically between 25° C. and 40° C. Alternatively, the dianhydrides were dissolved in one of these solvents, and the diamines were added to the dianhydride solution.

After the polyamic acid (or polyamic acid ester) is produced, the temperature of the reaction solution is then raised considerably to complete the dehydration ring closure. The temperatures used to complete the ring closure are typically from 150° C. to 200° C. A high temperature is used is to assure converting the polyamic acid into a polyimide. Optionally, a co-solvent can be used help remove the water produced during imidization (e.g., toluene, xylene and other aromatic hydrocarbons).

The chemical method includes the use of a chemical imidizing agent, which is used to catalyze the dehydration, or ring closing. Chemical imidization agents such as acetic anhydride and β-picoline can be used. The reaction solvent is not particularly limited so long as it is capable of dissolving the polyamic acid and polyimide. The resulting polyimide is then precipitated. This can be performed by adding the polyimide to a non-solvent. These non-solvents can be methanol, ethanol, or water. The solid is washed several times with the non-solvent, and the precipitate is oven dried.

Generally, thick-film compositions are mixed and then blended on a three-roll mill. Pastes are typically roll-milled for three or more passes at increasing levels of pressure until a suitable dispersion has been reached. After roll milling, the pastes may be formulated to printing viscosity requirements by addition of solvent.

Consolidation of the paste or liquid composition is accomplished by any number of standard curing methods including convection heating, forced air convection heating, vapor phase condensation heating, conduction heating, infrared heating, induction heating, or other techniques known to those skilled in the art.

One advantage that the polymers provide to the compositions of the invention is a relatively low consolidation temperature. The compositions can be consolidated with a temperature of equal to or less than 190° C. over a reasonable time period. This is particularly advantageous as it is compatible with printing wiring board processes and avoids oxidation of copper foil or damage or degradation to component properties.

It is to be understood, that the 190° C. temperature is not a maximum temperature that may be reached in a thermal profile. For example, the compositions can also be heated using a peak temperature up to about 350° C. with a short infrared cure. The term “short infrared cure” is defined as providing a curing profile with a high temperature spike over a period that ranges from a few seconds to a few minutes.

Another advantage that the polymers provide to the compositions of the inventions is a relatively high adhesion to prepreg when bonded to the prepreg using printed wiring board or IC package substrate lamination processes. This allows for reliable lamination processes and sufficient adhesion to prevent de-lamination in subsequent processes or use.

The encapsulant paste compositions of the invention can further include one or more metal adhesion agents. Preferred metal adhesion agents are selected from the group consisting of polybenzimidazole, 2-mercaptobenzimidazole (2-MB), and benzotriazole.

The compositions of the invention can also be provided in a solution and used in IC and wafer-level packaging as semiconductor stress buffers, interconnect dielectrics, protective overcoats (e.g., scratch protection, passivation, etch mask, etc.), bond pad redistribution, and solder bump underfills. One advantage provided by the compositions is the low consolidation temperature of less than 190° C. or short duration at peak temperature of 350° C. with short IR cure. Current packaging requires a cure temperature of about 300° C.±25° C.

As noted, the composition(s) of the present invention are useful in many applications. The composition(s) may be used as protection for any electronic, electrical or non-electrical component. For example, the composition(s) may be useful in integrated circuit packages, wafer-level packages and hybrid circuit applications in the areas of semiconductor junction coatings, semiconductor stress buffers, interconnect dielectrics, protective overcoats for bond pad redistribution, “glob top’ protective encapsulation of semiconductors, or solder bump underfills. Furthermore, the compositions may be useful in battery automotive ignition coils, capacitors, filters, modules, potentiometers, pressure sensitive devices, reisistors, switches, sensors, transformers, voltage regulators, lighting applications such as LED coatings for LED chip carriers and modules, sealing and joining medical and implantable devices, and solar cell coatings.

Test procedures used in the testing of the compositions of the invention and for the comparative examples are provided as follows:

Insulation Resistance

Insulation resistance of the capacitors is measured using a Hewlett Packard high resistance meter.

Temperature Humidity Bias (THB) Test

THB Test of ceramic capacitors embedded in printed wiring boards involves placing the printed wiring board in an environmental chamber and exposing the capacitors to 85° C., 85% relative humidity and a 5 volt DC bias. Insulation resistance of the capacitors is monitored every 24 hours. Failure of the capacitor is defined as a capacitor showing less than 50 meg-ohms in insulation resistance.

Brown Oxide Test

The device under test is exposed to an Atotech brown oxide treatment with a series of steps: (1) 60 sec. soak in a solution of 4-8% H₂SO4 at 40° C., (2) 120 sec. soak in soft water at room temperature, (3) 240 sec soak in a solution of 3-4% NaOH with 5-10% amine at 60° C., (4) 120 sec. soak in soft water at room temperature, (5) 120 sec. soak in 20 ml/l H₂O₂ and H₂SO4 base with additive at 40° C., (6) a soak for 120 sec. in a solution of Part A 280, Part B 40 ml/I at 40° C., and (7) a deionized water soak for 480 sec. at room temperature.

Insulation resistance of the capacitor is then measured after the test and failure is defined as a capacitor showing less than 50 Meg-Ohms.

Black Oxide Test

Black oxide processes are similar nature and scope to the brown oxide procedures described above, however the acid and base solutions in a traditional black oxide process can possess concentrations as high as 30%. Thus, the reliability of encapsulated dielectrics was evaluated after exposure to 30% sulfuric acid and 30% caustic solutions, 2 minute and 5 minute exposure times respectively.

Corrosion Resistance Test

Samples of the encapsulant are coated on copper foil and the cured samples are placed in a fixture that contacts the encapsulant coated side of the copper foil to 3% NaCl solution in water that is heated to 60° C. A 2V and 3V DC bias is applied respectively during this test. The corrosion resistance (Rₚ) is monitored periodically during a 10-hour test time.

Water Permeation Test

Samples of the encapsulant are coated on copper foil and the cured samples are placed in a fixture that contacts the encapsulant coated side of the copper foil to 3% NaCl solution in water that is heated to 60° C. No bias is applied during this test. The water permeation rate indicated by a capacitance increase was monitored periodically during a 10-hour test time.

Polyimide Film Moisture Absorption Test

The ASTM D570 method is used where polyimide solution is coated with a 20-mil doctor knife on a one oz. copper foil substrate. The wet coating is dried at 190° C. for about 1 hour in a forced draft oven to yield a polyimide film of 2 mils thickness. In order to obtain a thickness of greater than 5 mils as specified by the test method, two more layers are coated on top of the dried polyimide film with a 30 min 190° C. drying in a forced draft oven between the second and third coating. The three layer coating is dried 1 hr at 190° C. in a forced draft oven and then is dried in a 190° C. vacuum oven with a nitrogen purge for 16 hrs or until a constant weight is obtained. The polyimide film is removed from the copper substrate by etching the copper using commercially available acid etch technology. Samples of one inch by 3-inch dimensions are cut from the free-standing film and dried at 120° C. for 1 hour. The strips are weighed and immersed in deionized water for 24 hrs. Samples are blotted dry and weighed to determine the weight gain so that the percent water absorption can be calculated. Film samples were also placed in an 85/85 chamber for 48 hours to measure the water uptake of the samples under these conditions.

The following glossary contains a list of names and abbreviations for each ingredient used:

| | |
|---|---|
| 6FDA | 2,2-bis(3,4-dicarboxyphenyl)1,1,1,3,3, |
| | 3-hexafluoropropane dianhydride |
| TFMB | 4,4′-diamino-2,2′- |
| | bis(trifluoromethyl)biphenyl |
| 6F-AP | 2,2′-bis(3-amino-4-hydroxyphenyl) |
| | hexafluoropropane |
| Fumed silica | High surface area silica obtainable from |
| | several sources, such as Degussa. |
| Organosiloxane antifoam agent | Defoaming agent SWS-203 obtainable |
| | from Wacker Silicones Corp. |

### EXAMPLES

### Example 1

A polyimide was prepared by conversion of a polyamic acid to polyimide with chemical imidization. To a dry three neck round bottom flask equipped with nitrogen inlet, mechanical stirrer and condenser was added 800.45 grams of DMAC, 89.98 grams of 3,3′-bis-(trifluoromethyl)benzidine (TFMB), 3.196 grams 3,3′-dihydroxy-4,4′-diaminobiphenyl (HAB) and 0.878 grams of phthalic anhydride (to control molecular weight).

To this stirred solution was added over one hour 104.87 grams of 3,3′,4,4′-diphenylsulfone tetracarboxylic dianhydride (DSDA). The solution of polyamic acid reached a temperature of 33° C. and was stirred without heating for 16 hrs. 119.56 grams of acetic anhydride were added followed by 109.07 grams of 3-picoline and the solution was heated to 80° C. for 1 hour.

The solution was cooled to room temperature, and the solution added to an excess of methanol in a blender to precipitate the product polyimide. The solid was collected by filtration and was washed 2 times by re-blending the solid in methanol. The product was dried in a vacuum oven with a nitrogen purge at 150° C. for 16 hrs to yield 188.9 grams of product having a number average molecular weight of 46,300 and a weight average molecular weight of 93,900. The molecular weight of the polyimide polymer was obtained by size exclusion chromatography using polystyrene standards. Some of the phenolic groups were acetylated under the conditions used to chemically dehydrate the poly(amic acid) as determined by NMR analysis.

The polyimide was dissolved at 20% solids in a 60/40 weight/weight mixture of propyleneglycol diacetate (PGDA)/Dowanol® PPh.

### Example 2

A polyimide based on 6FDA and TFMB was prepared according to the procedure in Example 1. The yield was 181 g, the number average molecular weight was 48,500 g/m according to GPC analysis, the weight average molecular weight was 110,000 g/m. The polyimide was dissolved at 25% solids in DBE-2. The polyimide was also dissolved at 25% solids by weight in butyl carbitol acetate.

### Example 3

A polyimide based on 6FDA, TFMB, and 6F-AP (90/10 amine molar ratio) was prepared according to the procedure in Example 1. The yield was 185 g, the number average molecular weight was 44,200 g/m according to GPC analysis, the weight average molecular weight was 93,000 g/m. The polyimide was dissolved at 20% solids in butyl carbitol acetate.

### Example 4

A polyimide based on 6FDA, TFMB, and 6F-AP (75/25 amine molar ratio) was prepared according to the procedure in Example 1. The yield was 178 g, the number average molecular weight was 39,600 g/m according to GPC analysis, the weight average molecular weight was 84,700 g/m. The polyimide was dissolved at 20% solids in butyl carbitol acetate.

### Example 5

An encapsulant composition was prepared according to the following composition and procedure:

| Material | Weight (g) |
|---|---|
| Polymer solution from Example 2 (DBE-2) | 40 |
| Fumed silica (CAB-O-SIL TS-500) | 2.5 |

### The mixture was roll milled with a 1-mil gap with 3 passes each at 0, 50, 100, 200, 250 and 300 psi to yield well dispersed paste.

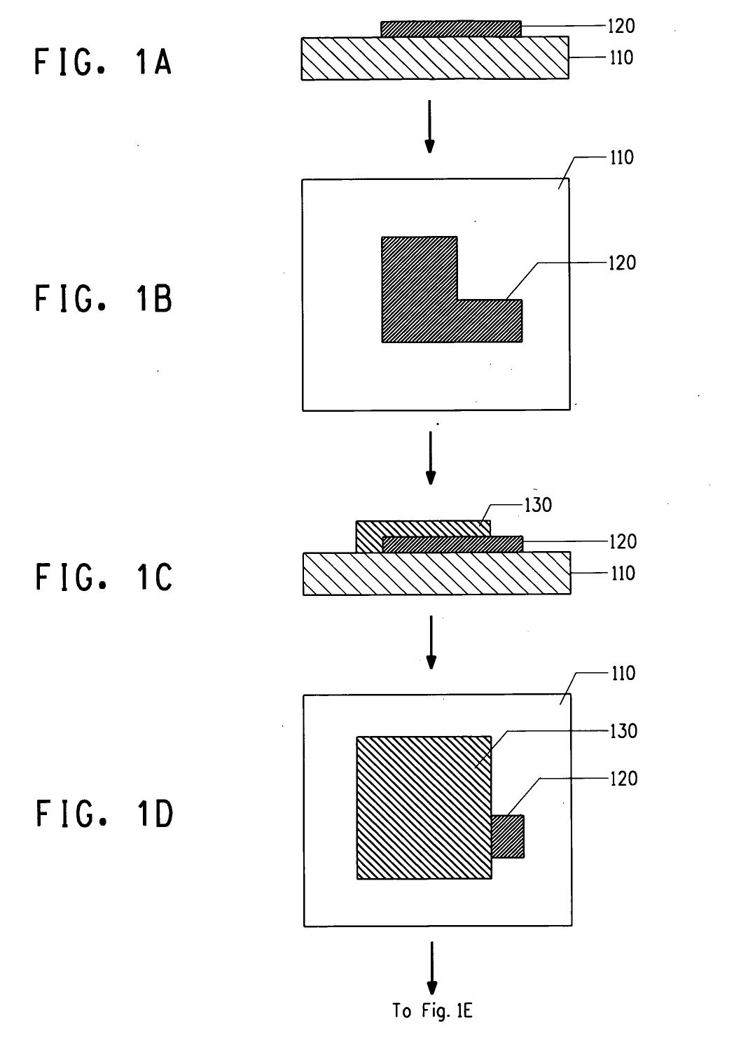

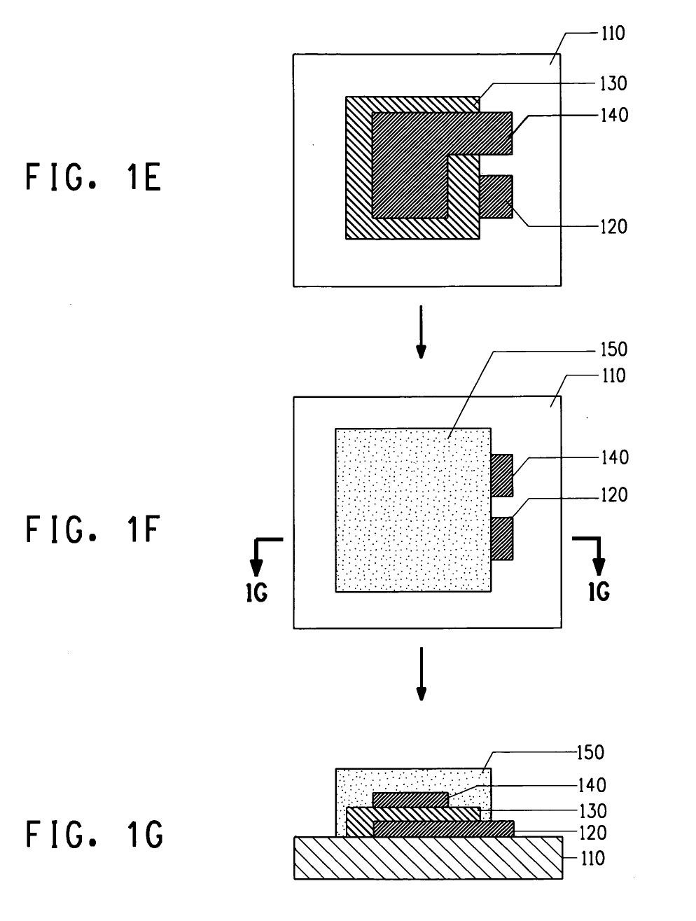

Capacitors on commercial 96% alumina substrates were covered by encapsulant compositions and used as a test vehicle to determine the encapsulants resistance to selected chemicals. The test vehicle was prepared in the following manner as schematically illustrated in FIG. 1A through 1G.

As shown in FIG. 1A, electrode material (EP 320 obtainable from E. I. du Pont de Nemours and Company) was screen-printed onto the alumina substrate to form electrode pattern 120. As shown in FIG. 1B, the area of the electrode was 0.3 inch by 0.3 inch and contained a protruding “finger” to allow connections to the electrode at a later stage. The electrode pattern was dried at 120° C. for 10 minutes and fired at 930° C. under copper thick-film nitrogen atmosphere firing conditions.

As shown in FIG. 1C, dielectric material (EP 310 obtainable from E. I. du Pont de Nemours and Company) was screen-printed onto the electrode to form dielectric layer 130. The area of the dielectric layer was approximately 0.33 inch by 0.33 inch and covered the entirety of the electrode except for the protruding finger. The first dielectric layer was dried at 120° C. for 10 minutes. A second dielectric layer was then applied, and also dried using the same conditions. A plan view of the dielectric pattern is shown in FIG. 1D.

As shown in FIG. 1E, copper paste EP 320 was printed over the second dielectric layer to form electrode pattern 140. The electrode was 0.3 inch by 0.3 inch but included a protruding finger that extended over the alumina substrate. The copper paste was dried at 120° C. for 10 minutes.

The first dielectric layer, the second dielectric layer, and the copper paste electrode were then co-fired at 930° C. under copper thick-film firing conditions. The encapsulant composition was screen printed through a 325 mesh screen over the entirety of the capacitor electrode and dielectric except for the two fingers using the pattern shown in FIG. 1F to form a 0.4 inch by 0.4 inch encapsulant layer 150. The encapsulant layer was dried for 10 minutes at 120° C. Another layer of encapsulant was printed and dried for 10 minutes at 120° C. A side view of the final stack is shown in FIG. 1G. The two layers of encapsulant were then baked under nitrogen in a forced draft oven at 190° C. for 30 minutes. The final cured thickness of the encapsulant was approximately 10 microns.

After encapsulation, the average capacitance of the capacitors was 41.4 nF, the average loss factor was 1.5%, the average insulation resistance was 2.2 Gohms. The coupons were then dipped in a 5% sulfuric acid solution at room temperature for 6 minutes, rinsed with deionized water, then dried at 120° C. for 30 minutes. The average capacitance, loss factor, and insulation resistance were 40.8 nf, 1.5%, 1.9 Gohm respectively after the acid treatment. Unencapsulated coupons did not survive the acid and base exposures.

Three inch squares of the encapsulant paste were also printed and cured on 6″ square one oz. copper sheets to yield defect-free coatings suitable for corrosion resistance testing as described above. The coatings were exposed for 12 hours to a 3% NaCl solution under 2V and 3V DC bias. The corrosion resistance remained above 7×10⁹ ohms.cm² at 0.01 Hz, during the test.

In a water permeation test, the encapsulant film capacitance remained unchanged during an immersion time of >450 minutes. Coupons were prepared according to the procedure outlined in Example 11. Using these test coupons, the adhesion of the encapsulant was measured to be 2.2 lbf/inch over the copper electrode and 2.8 lbf/inch over the capacitor dielectric. The average water uptake as determined by the film moisture absorption test was 0.16% under 85/85 conditions.

### Example 6

An encapsulant with the following composition containing 11% by weight CAB-O-SIL TS-500 fumed silica was prepared according to the procedure outlined in Example 5.

| Material | Weight (g) |
|---|---|
| Polymer solution from Example 2 (DBE-2) | 40.0 g |
| Fumed silica (CAB-O-SIL TS-500) | 5 g |

The encapsulant was printed and cured over the capacitors prepared on alumina substrates as described in Example 5. To evaluate the encapsulant stability in the presence of strong acids and bases, selected coupons were then dipped in a 5% sulfuric acid solution at 45° C. for 2 minutes, rinsed with deionized water, then dried at 120° C. for 30 minutes. Additional coupons were exposed to a 5% sodium hydroxide bath at 60° C. for 5 minutes. After exposure, these coupons were also rinsed with deionized water and dried prior to testing. The table below summarizes capacitor properties before and after acid and base exposure.

| | | | Insulation |
|---|---|---|---|
| | Capacitance | | Resistance |
| Condition | (nF) | Dissipation factor (%) | (Gohm) |
| After encapsulation | 35.5 | 1.4 | 3.4 |
| After base treatment | 36.9 | 1.5 | 4.1 |
| After acid treatment | 36.0 | 1.5 | 3.7 |

Unencapsulated coupons did not survive the acid and base exposures.

Three inch squares of the encapsulant paste were also printed and cured on 6″ square one oz. copper sheets to yield defect-free coatings suitable for corrosion resistance testing as described above. The coatings were exposed for 12 hours to a 3% NaCl solution under 2V and 3V DC bias. The corrosion resistance remained above 7×10⁹ ohms.cm² at 0.01 Hz, during the test.

In a water permeation test, the encapsulant film capacitance remained unchanged during an immersion time of >450 minutes. Coupons were prepared according to the procedure outlined in Example 11. Using these test coupons, the adhesion of the encapsulant was measured to be 3.6 lbf/inch over the copper electrode and 4.0 lbf/inch over the capacitor dielectric. The average water uptake as determined by the film moisture absorption test was 0.12% under 85/85 conditions.

### Example 7

An encapsulant with the following composition containing 5.8% by weight CAB-O-SIL TS-500 fumed silica was prepared according to the procedure outlined in Example 5.

| Material | Weight (g) |
|---|---|
| Polymer solution from Example 3 | 40.0 g |
| Fumed silica (CAB-O-SIL TS-500) | 2.5 g |

The encapsulant was printed and cured over the capacitors prepared on alumina substrates as described in Example 5. To evaluate the encapsulant stability in the presence of strong acids and bases, selected coupons were then dipped in a 5% sulfuric acid solution at 45° C. for 2 minutes, rinsed with deionized water, then dried at 120° C. for 30 minutes. Additional coupons were exposed to a 5% sodium hydroxide bath at 60° C. for 5 minutes. After exposure, these coupons were also rinsed with deionized water and dried prior to testing. The table below summarizes capacitor properties before and after acid and base exposure.

| | | | Insulation |
|---|---|---|---|
| | Capacitance | | Resistance |
| Condition | (nF) | Dissipation factor (%) | (Gohm) |
| After encapsulation | 39.5 | 1.5 | 3.4 |
| After base treatment | 40.4 | 1.5 | 3.1 |
| After acid treatment | 39.2 | 1.5 | 3.7 |

Unencapsulated coupons did not survive the acid and base exposures.

Three inch squares of the encapsulant paste were also printed and cured on 6″ square one oz. copper sheets to yield defect-free coatings suitable for corrosion resistance testing as described above. The coatings were exposed for 12 hours to a 3% NaCl solution under 2V and 3V DC bias. The corrosion resistance remained above 7×10⁹ ohms.cm² at 0.01 Hz, during the test.

In a water permeation test, the encapsulant film capacitance remained unchanged during an immersion time of >450 minutes. Coupons were prepared according to the procedure outlined in Example 11. Using these test coupons, the adhesion of the encapsulant was measured to be 4.2 lbf/inch over the copper electrode and 4.6 lbf/inch over the capacitor dielectric. The average water uptake as determined by the film moisture absorption test was 0.27% under 85/85 conditions.

### Example 8

An encapsulant with the following composition containing 5.8% by weight CAB-O-SIL TS-500 fumed silica was prepared according to the procedure outlined in Example 5.

| Material | Weight (g) |
|---|---|
| Polymer solution from Example 4 | 40.0 g |
| Fumed silica (CAB-O-SIL TS-500) | 2.5 g |

The encapsulant was printed and cured over the capacitors prepared on alumina substrates as described in Example 5. To evaluate the encapsulant stability in the presence of strong acids and bases, selected coupons were then dipped in a 5% sulfuric acid solution at 45° C. for 2 minutes, rinsed with deionized water, then dried at 120° C. for 30 minutes. Additional coupons were exposed to a 5% sodium hydroxide bath at 60° C. for 5 minutes. After exposure, these coupons were also rinsed with deionized water and dried prior to testing. The table below summarizes capacitor properties before and after acid and base exposure.

| | | | Insulation |
|---|---|---|---|
| | Capacitance | | Resistance |
| Condition | (nF) | Dissipation factor (%) | (Gohm) |
| After encapsulation | 42.5 | 1.4 | 4.1 |
| After base treatment | 41.4 | 1.5 | 3.9 |
| After acid treatment | 40.2 | 1.4 | 3.7 |

Unencapsulated coupons did not survive the acid and base exposures.

Three inch squares of the encapsulant paste were also printed and cured on 6″ square one oz. copper sheets to yield defect-free coatings suitable for corrosion resistance testing as described above. The coatings were exposed for 12 hours to a 3% NaCl solution under 2V and 3V DC bias. The corrosion resistance remained above 7×10⁹ ohms.cm² at 0.01 Hz, during the test.

In a water permeation test, the encapsulant film capacitance remained unchanged during an immersion time of >450 minutes. Coupons were prepared according to the procedure outlined in Example 11. Using these test coupons, the adhesion of the encapsulant was measured to be 4.1 lbf/inch over the copper electrode and 4.4 lbf/inch over the capacitor dielectric. The average water uptake as determined by the film moisture absorption test was 0.31% under 85/85 conditions.

### Example 9

An encapsulant based on the polymer solution from Example 3 was printed and cured over the capacitors prepared on alumina substrates as described in Example 5. No silica was added to this sample so roll milling was not necessary. To evaluate the encapsulant stability in the presence of strong acids and bases, selected coupons were then dipped in a 5% sulfuric acid solution at 45° C. for 2 minutes, rinsed with deionized water, then dried at 120° C. for 30 minutes. Additional coupons were exposed to a 5% sodium hydroxide bath at 60° C. for 5 minutes. After exposure, these coupons were also rinsed with deionized water and dried prior to testing. The table below summarizes capacitor properties before and after acid and base exposure.

| | | | Insulation |
|---|---|---|---|
| | Capacitance | | Resistance |
| Condition | (nF) | Dissipation factor (%) | (Gohm) |
| After encapsulation | 38.5 | 1.5 | 3.1 |
| After base treatment | 39.4 | 1.5 | 3.9 |
| After acid treatment | 39.2 | 1.5 | 3.2 |

Unencapsulated coupons did not survive the acid and base exposures.

Three inch squares of the encapsulant paste were also printed and cured on 6″ square one oz. copper sheets to yield defect-free coatings suitable for corrosion resistance testing as described above. The coatings were exposed for 12 hours to a 3% NaCl solution under 2V and 3V DC bias. The corrosion resistance remained above 7×10⁹ ohms.cm² at 0.01 Hz, during the test.

In a water permeation test, the encapsulant film capacitance remained unchanged during an immersion time of >450 minutes. Coupons were prepared according to the procedure outlined in Example 11. Using these test coupons, the adhesion of the encapsulant was measured to be 4.4 lbf/inch over the copper electrode and 4.8 lbf/inch over the capacitor dielectric. The average water uptake as determined by the film moisture absorbtion test was 0.29% under 85/85 conditions.

### Example 10

An encapsulant based on the polymer solution from Example 4 was printed and cured over the capacitors prepared on alumina substrates as described in Example 5. No silica was added to this sample so roll milling was not necessary. To evaluate the encapsulant stability in the presence of strong acids and bases, selected coupons were then dipped in a 5% sulfuric acid solution at 45° C. for 2 minutes, rinsed with deionized water, then dried at 120° C. for 30 minutes. Additional coupons were exposed to a 5% sodium hydroxide bath at 60° C. for 5 minutes. After exposure, these coupons were also rinsed with deionized water and dried prior to testing. The table below summarizes capacitor properties before and after acid and base exposure.

| | | | Insulation |
|---|---|---|---|
| | Capacitance | | Resistance |
| Condition | (nF) | Dissipation factor (%) | (Gohm) |
| After encapsulation | 41.7 | 1.4 | 3.9 |
| After base treatment | 42.4 | 1.5 | 3.1 |
| After acid treatment | 43.2 | 1.5 | 3.6 |

Unencapsulated coupons did not survive the acid and base exposures.

Three inch squares of the encapsulant paste were also printed and cured on 6″ square one oz. copper sheets to yield defect-free coatings suitable for corrosion resistance testing as described above. The coatings were exposed for 12 hours to a 3% NaCl solution under 2V and 3V DC bias. The corrosion resistance remained above 7×10⁹ ohms.cm² at 0.01 Hz, during the test.

In a water permeation test, the encapsulant film capacitance remained unchanged during an immersion time of >450 minutes. Coupons were prepared according to the procedure outlined in Example 11. Using these test coupons, the adhesion of the encapsulant was measured to be 4.1 lbf/inch over the copper electrode and 4.3 lbf/inch over the capacitor dielectric. The average water uptake as determined by the film moisture absorption test was 0.33% under 85/85 conditions.

### Example 11

An encapsulant based on the polymer solution from Example 2 (butyl carbitol acetate solvent) was printed and cured over the capacitors prepared on alumina substrates as described in Example 5. No silica was added to this sample so roll milling was not necessary. To evaluate the encapsulant stability in the presence of strong acids and bases, selected coupons were then dipped in a 5% sulfuric acid solution at 45° C. for 2 minutes, rinsed with deionized water, then dried at 120° C. for 30 minutes. Additional coupons were exposed to a 5% sodium hydroxide bath at 60° C. for 5 minutes. After exposure, these coupons were also rinsed with deionized water and dried prior to testing. The table below summarizes capacitor properties before and after acid and base exposure.

| | | | Insulation |
|---|---|---|---|
| | Capacitance | | Resistance |
| Condition | (nF) | Dissipation factor (%) | (Gohm) |
| After encapsulation | 38.7 | 1.4 | 3.2 |
| After base treatment | 39.4 | 1.5 | 3.1 |
| After acid treatment | 38.2 | 1.4 | 3.3 |

Unencapsulated coupons did not survive the acid and base exposures.

Three inch squares of the encapsulant paste were also printed and cured on 6″ square one oz. copper sheets to yield defect-free coatings suitable for corrosion resistance testing as described above. The coatings were exposed for 12 hours to a 3% NaCl solution under 2V and 3V DC bias. The corrosion resistance remained above 7×10⁹ ohms.cm² at 0.01 Hz, during the test.

In a water permeation test, the encapsulant film capacitance remained unchanged during an immersion time of >450 minutes. Coupons were prepared according to the procedure outlined in Example 11. Using these test coupons, the adhesion of the encapsulant was measured to be 3.6 lbf/inch over the copper electrode and 3.8 lbf/inch over the capacitor dielectric. The average water uptake as determined by the film moisture absorption test was 0.23% under 85/85 conditions.

### Example 12

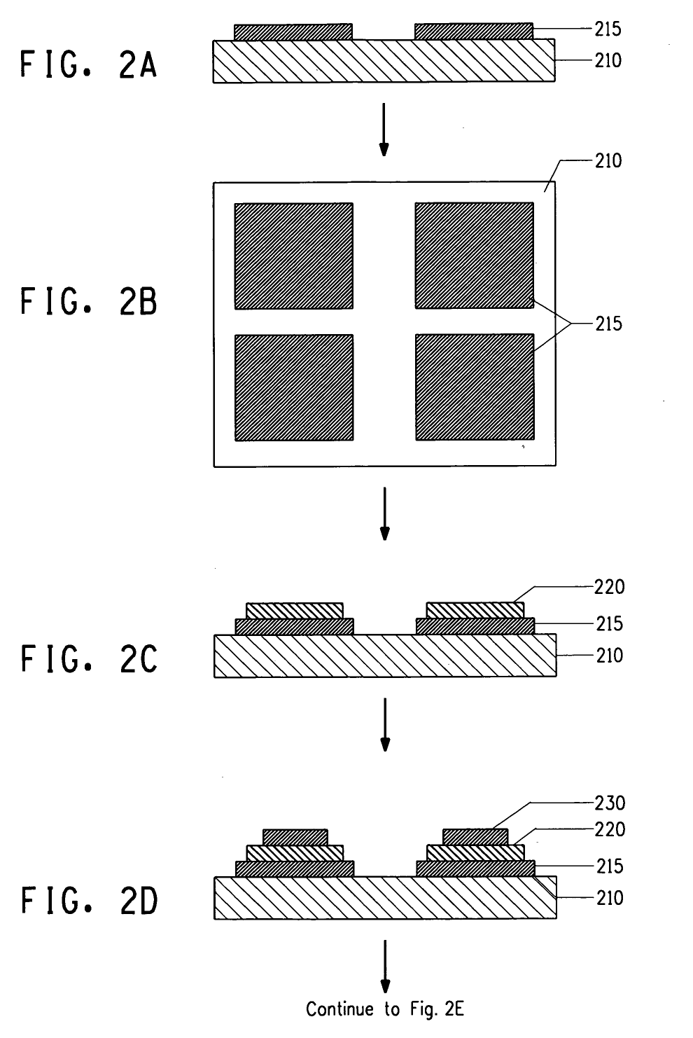

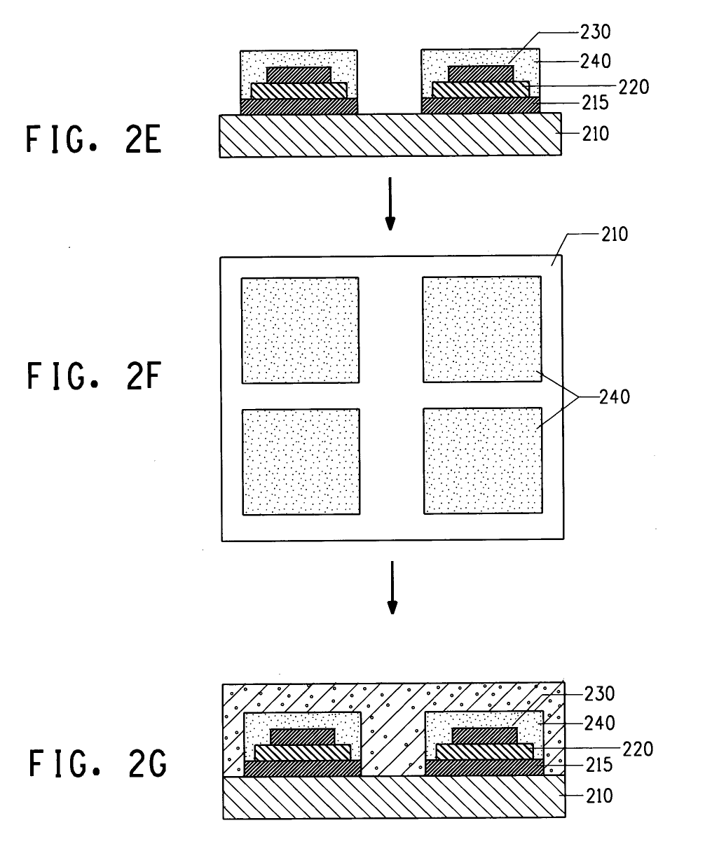

Fired-on-foil capacitors were fabricated for use as a test structure using the following process. As shown in FIG. 2A, a 1 ounce copper foil 210 was pretreated by applying copper paste EP 320 (obtainable from E. I. du Pont de Nemours and Company) as a preprint to the foil to form the pattern 215 and fired at 930° C. under copper thick-film firing conditions. Each preprint pattern was approximately 1.67 cm by 1.67 cm. A plan view of the preprint is shown in FIG. 2B.

As shown in FIG. 2C, dielectric material (EP 310 obtainable from E. I. du Pont de Nemours and Company) was screen-printed onto the preprint of the pretreated foil to form pattern 220. The area of the dielectric layer was 1.22 cm by 1.22.cm. and within the pattern of the preprint. The first dielectric layer was dried at 120° C. for 10 minutes. A second dielectric layer was then applied, and also dried using the same conditions.

As shown in FIG. 2D, copper paste EP 320 was printed over the second dielectric layer and within the area of the dielectric to form electrode pattern 230 and dried at 120° C. for 10 minutes. The area of the electrode was 0.9 cm by 0.9 cm.

The first dielectric layer, the second dielectric layer, and the copper paste electrode were then co-fired at 930° C. under copper thick-film firing conditions.

The encapsulant composition as described in Example 6 was double-printed through a 325 mesh screen over capacitors to form encapsulant layer 240 using the pattern as shown in FIG. 2E. The encapsulant was dried and cured using various profiles. The cured encapsulant thickness was approximately 10 microns. A plan view of the structure is shown in FIG. 2F. The component side of the foil was laminated to 1080 BT resin prepreg 250 at 375° F. at 400 psi for 90 minutes to form the structure shown in FIG. 2G. The adhesion of the prepreg to the encapsulant was tested using the IPC-TM-650 adhesion test number 2.4.9. The adhesion results are shown below:

| | | | Encapsulant |
|---|---|---|---|
| | | Encapsulant over Cu | over Capacitor |
| Dry Cycle | Cure Cycle | (lb force/inch) | (lb force/inch) |
| 80° C./5 min | 190° C./30 min | 3.6 | 3.9 |
| 100° C./5 min | 150° C./30 min | 3.8 | 4.1 |
| 120° C./10 min | 190° C./30 min | 3.5 | 3.7 |

showing that the adhesion over the capacitor and to the prepreg was quite acceptable over a range of heating conditions.

What is claimed is:

1. A composition comprising a polyimide, and an organic solvent.

2. The composition of claim 1, wherein the polyimide comprises a repeat unit of the formula: 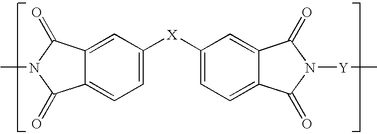
wherein X is SO₂ or C(CF₃)₂, C(CF₃)phenyl, C(CF₃)CF₂CF₃, or C(CF₂CF₃)phenyl, and combinations thereof, and
wherein Y is a diamine.

3. The composition of claim 2, wherein—0 to 30 mole percent of the diamine is selected from the group consisting of 2,2′-bis(3-amino4-hydroxyphenyl)hexafluoropropane (6F-AP), 3,3′-dihydroxy-4,4′-diaminobiphenyl (HAB), 2,4-diaminophenol, 2,3-diaminophenol, 3,3′-diamino-4,4′-dihydroxy-biphenyl and 2,2′-bis(3-amino-3-hydroxyphenyl)hexafluoropropane,
and wherein the mole percent of the diamine is based on the total moles of diamine in the composition.

4. The composition of claim 3, wherein 30 to 100 mole percent of the diamine is selected from the group consisting of 3,4′-diaminodiphenyl ether (3,4′-ODA), 4,4′-diamino-2,2′-bis(trifluoromethyl)biphenyl (TFMB), 3,3′,5,5′-tetramethylbenzidine, 2,3,5,6-tetramethyl-1,4-phenylenediamine, 3,3′-diaminodiphenyl sulfone, 3,3′dimethylbenzidine, 3,3′-bis(trifluoromethyl)benzidine, 2,2′-bis-(p-aminophenyl)hexafluoropropane, bis(trifluoromethoxy)benzidine (TFMOB), 2,2′-bis(pentafluoroethoxy)benzidine (TFEOB), 2,2′-trifluoromethyl-4,4′-oxydianiline (OBABTF), 2-phenyl-2-trifluoromethyl-bis(p-aminophenyl)methane, 2-phenyl-2-trifluoromethyl-bis(m-aminophenyl)methane, 2,2′-bis(2-heptafluoroisopropoxy-tetrafluoroethoxy)benzidine (DFPOB), 2,2-bis(m-aminophenyl)hexafluoropropane (6-FmDA), 2,2-bis(3-amino4-methylphenyl)hexafluoropropane, 3,6-bis(trifluoromethyl)-1,4-diaminobenzene (2TFMPDA), 1-(3,5-diaminophenyl)-2,2-bis(trifluoromethyl-3,3,4,4,5,5,5-heptafluoropentane, 3,5-diaminobenzotrifluoride (3,5-DABTF), 3,5-diamino-5-(pentafluoroethyl)benzene, 3,5-diamino-5-(heptafluoropropyl)benzene, 2,2′-dimethylbenzidine (DMBZ), 2,2′,6,6′-tetramethylbenzidine (TMBZ), 3,6-diamino-9,9-bis(trifluoromethyl)xanthene (6FCDAM), 3,6-diamino-9-trifluoromethyl-9-phenylxanthene (3FCDAM), 3,6-diamino-9,9-diphenyl xanthene and combinations thereof,
and wherein the mole percent of the diamine is based on the total moles of diamine in the composition.

5. The composition of claim 1, wherein the polyimide comprises a dianhydride and a diamine.

6. The composition of claim 5, wherein 0 to 30 mole percent of the diamine is selected from the group consisting of 2,2′-bis(3-amino-4-hydroxyphenyl)hexafluoropropane (6F-AP), 3,3′-dihydroxy-4,4′-diaminobiphenyl (HAB), 2,4-diaminophenol, 2,3-diaminophenol, 3,3′-diamino-4,4′-dihydroxy-biphenyl and 2,2′-bis(3-amino-3-hydroxyphenyl)hexafluoropropane,
and wherein the mole percent of the diamine is based on the total moles of diamine in the composition.

7. The composition of claim 6, wherein the dianhydride is selected from the group consisting of 3,3′,4,4′-diphenylsulfone tetracarboxylic dianhydride (DSDA), 2,2-bis(3,4-dicarboxyphenyl) 1,1,1,3,3,3-hexafluoropropane dianhydride (6-FDA), 1-phenyl-1,1-bis(3,4-dicarboxyphenyl)-2,2,2-trifluoroethane dianhydride, 1,1,1,3,3,4,4,4-octylfluoro-2,2-bis(3,4-dicarboxyphenyl)butane dianhydride, 1-phenyl-2,2,3,3,3-pentafluoro-1,1-bis(3,4-dicarboxylphenyl)propane dianhydride, 4,4′-oxydiphthalic anhydride (ODPA), 2,2′-bis(3,4-dicarboxyphenyl)propane dianhydride, 2,2′-bis(3,4-dicarboxyphenyl)-2-phenylethane dianhydride, 2,3,6,7-tetracarboxy-9-trifluoromethyl-9-phenylxanthene dianhydride (3FCDA), 2,3,6,7-tetracarboxy-9,9-bis(trifluoromethyl)xanthene dianhydride (6FCDA), 2,3,6,7-tetracarboxy-9-methyl-9-trifluoromethylxanthene dianhydride (MTXDA), 2,3,6,7-tetracarboxy-9-phenyl-9-methylxanthene dianhydride (MPXDA), 2,3,6,7-tetracarboxy-9,9-dimethylxanthene dianhydride (NMXDA) and combinations thereof.

8. The composition of claim 2 wherein the water absorption is 1% or less.

9. The composition of claim 1 further comprising one or more inorganic functional fillers, defoamers and colorants

10. The composition of claim 9 wherein said inorganic functional fillers are electrically-insulating fillers selected from the group consisting of titanium dioxide, alumina, talc and fumed silica.

11. The composition of claim 9 wherein said inorganic functional fillers are metals or metal compounds.

12. The composition of claim 10 wherein the composition is used to make an encapsulant for ceramic capacitors embedded in printed wiring boards.

13. The composition of claim 12 wherein the composition provides protection to capacitors when immersed in 30% sulfuric acid and 30% sodium hydroxide.

14. The composition of claim 12 wherein the encapsulant exhibits a peel strength over the capacitor of >2 lbf/inch.

15. The composition of claim 12 wherein the encapsulant provides enhanced protection to the capacitor during an accelerated life test of exposure to humidity, elevated temperature and DC bias.

16. The composition of claim 12 wherein the composition has a consolidation temperature of equal to or less than 190° C. or can be consolidated at a peak temperature up to about 350° C. with a short infrared cure.

17. The composition of claim 12 wherein the composition is used to fill an etched trench.

18. The composition of claim 12 wherein the composition is used as protection for any electrical or non-electrical component, in integrated circuit package, wafer-level package and hybrid circuit applications in the areas of semiconductor junction coatings, semiconductor stress buffers, interconnect dielectrics, protective overcoats for bond pad redistribution, “glob top’ protective encapsulation of semiconductors, or solder bump underfills.

19. A method of making an encapsulant composition comprising:
combining one or more polyimides with water absorption of less than 2%, one or more inorganic, electrically insulating fillers; a defoamer and an organic solvent to provide an encapsulant composition;
applying the encapsulant composition to a substrate; and
consolidating the applied encapsulant composition.

20. The method of claim 19 wherein polyimide comprises a repeat unit of the formula: 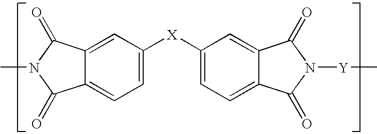
wherein X is SO₂ or C(CF₃)₂, C(CF₃)phenyl, C(CF₃)CF₂CF₃, or C(CF₂CF₃)phenyl, and combinations thereof, and
wherein Y is a diamine.

21. The method of claim 20 wherein the consolidation of the applied encapsulant composition includes a heating temperature of equal to or less than 190□ C. or a peak temperature up to about 350° C. with a short infrared cure.

22. The method of claim 17 wherein the polyimide has water absorption of 1% or less.
